(19) United States
(12) Patent Application Publication
(10) Pub. No.: US 2005/0232446 A1
(43) Pub. Date: Oct. 20, 2005

(54) Trickle-charged amplifier

(76) Inventor: Larry Kirn, East Lansing, MI (US)

Correspondence Address: John G. Posa;Gifford, Krass, Groh, Sprinkle,, Anderson & Citkowski, P.C., PO Box 7021, Troy, MI, 48007-7021, US

(21) Appl. No.: 11/107,713

(22) Filed: Apr. 15, 2005

Related U.S. Application Data
(60) Provisional application No. 60/562,398, filed on Apr. 15, 2004.

(51) Int. Cl. H04R 3/00; H03F 21/00

(52) U.S. Cl. 381/111; 381/120

(57) ABSTRACT

A long-term power storage device associated with an amplifier is trickle-charged by a relatively low-power source. In that amplification has a very large peak-to-average power ratio, high output levels can be obtained from a low average input power. Furthermore, since most amplification use is not constant, refractory periods exist wherein battery recharging can occur.

### REFERENCE TO RELATED APPLICATION

This application claims priority to U.S. Provisional Patent Application Ser. No. 60/562,398, filed Apr. 15, 2004, the entire content of which is incorporated herein by reference.

### FIELD OF THE INVENTION

This invention relates generally to audio amplifiers and, in particular, to the inclusion of an energy storage device with an amplifier which is trickle-charged by a relatively low-power source.

### BACKGROUND OF THE INVENTION

Due to the low acoustic efficiency of most loudspeakers, audio amplifiers typically demand large amounts of power. This high power requirement during use usually imposes high power distribution directly to the amplifier, adding system cost. A need exists to reduce the power distribution to amplifiers.

### SUMMARY OF THE INVENTION

The present invention resides in the inclusion of a long-term power storage device with an amplifier which is trickle-charged by a relatively low-power source. In that amplification has a very large peak-to-average power ratio, high output levels can be obtained from a low average input power. Furthermore, since most amplification use is not constant, refractory periods exist wherein battery recharging can occur.

### BRIEF DESCRIPTION OF THE DRAWINGS

FIG. 1 is a block diagram of a preferred embodiment of the present invention.

### DETAILED DESCRIPTION OF THE INVENTION

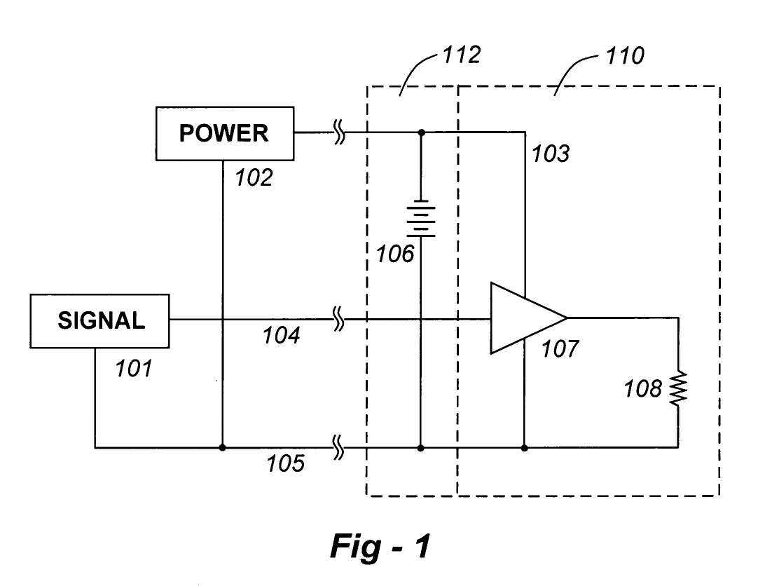

Referring now to FIG. 1, signal source 101 provides a signal through conductor 104 to amplifier 107, which directly drives load 108. Power source 102 provides power to amplifier 107 through conductor 103. The return path for both signal source 101 and power source 102, as well as amplifier 107 and load 108, is provided by conductor 105. Battery 106 receives power from power source 102 through conductor 103, with return through conductor 105, and subsequently provides power to amplifier 107. Note that signal source 101 and power source 102 may be remote from the remainder of the circuitry, which may necessitate lengthy conductors 103, 104, and 105. Note also that the “battery” in this case may include supercapacitors, ultracapacitors, and the like.

Due to the length, and resultant resistance of conductors 103 and 105, it can be seen that high peak power will be primarily supplied to amplifier 107 by battery 106. During periods of low or zero power, it also can be seen that battery 106 will be charged by power source 102. The current capability of conductors thus can be seen to be only that required to charge battery 106, a capability significantly lower than the demand of amplifier 107 at peak output power.

A further advantage of the invention is reduced distortion caused by the current reduction in common return conductor 105. It should be apparent that the present invention significantly reduces long-term average power, and hence necessary size, of both power supply and return conductors. The amplifier and speaker, or amplifier, speaker and battery/capacitor may be contained in a common enclosure, as indicated with 110 and 112 in FIG. 1.

1. An integrated power speaker adapted for connection to a relatively low-power source, comprising:
an enclosure;
a speaker and amplifier disposed within the enclosure; and
a power storage device within the enclosure that is charged by the power source upon demand.

2. The integrated power speaker of claim, wherein the power storage device is a battery.

3. The integrated power speaker of claim, wherein the power storage device is a capacitor.
